(19) United States
(12) Patent Application Publication
(10) Pub. No.: US 2024/0087648 A1
(43) Pub. Date: Mar. 14, 2024

(54) THREE-DIMENSIONAL FLASH MEMORY FOR IMPROVING CONTACT RESISTANCE OF IGZO CHANNEL LAYER

(71) Applicant: IUCF-HYU (Industry University Cooperation Foundation Hanyang University), Seoul (KR)

(72) Inventors: Yun Heub Song, Seoul (KR); Jae Kyung Jung, Seoul (KR)

(73) Assignee: IUCF-HYU (Industry University Cooperation Foundation Hanyang University), Seoul (KR)

(21) Appl. No.: 18/261,015

(22) PCT Filed: Nov. 25, 2021
(86) PCT No.: PCT/KR2021/017521

§ 371 Date: Jul. 11, 2023

(30) Foreign Application Priority Data
Jan. 12, 2021 (KR) 10-2021-0003678

(51) Int. Cl. G11C 16/04; H10B 43/27

(52) U.S. Cl. CPC G11C 16/0483; H10B 43/27

(57) ABSTRACT

Disclosed are a three-dimensional flash memory for improving contact resistance of IGZO channel layer and a method for manufacturing same. According to one embodiment, the three-dimensional flash memory may comprise: multiple word lines sequentially stacked and extending in a horizontal direction on a substrate; and at least one string extending in a vertical direction on the substrate through the multiple word lines, the at least one string comprising a channel layer extending in the vertical direction and a charge storage layer formed to surround the channel layer, wherein the at least one string comprises a drain junction formed in a dual structure and comprising an N+ doped first area on the channel layer and an N+ doped second area with a material having lower contact resistance than the channel layer.

### TECHNICAL FIELD

The following embodiments relate to a three-dimensional flash memory, and more particularly, to a technology for improving contact resistance of an indium gallium zinc oxide (IGZO) channel layer.

### BACKGROUND ART

Flash memory elements are electrically erasable programmable read only memories (EEPROMs), and the memories may be commonly used in, for example, computers, digital cameras, MP3 players, game systems, memory sticks, and the like. Such flash memory elements electrically control input/output of data by Fowler-Nordheim tunneling or hot electron injection.

In detail, referring to FIG. 1 illustrating an array of a three-dimensional flash memory according to the related art, the array of the three-dimensional flash memory may include a common source line CSL, a bit line BL, and a plurality of cell strings CSTR arranged between the common source line CSL and the bit line BL.

The bit lines are two-dimensionally arranged, and the plurality of cell strings CSTR are connected in parallel to the bit lines. The cell strings CSTR may be commonly connected to the common source line CSL. That is, the plurality of cell strings CSTR may be arranged between the plurality of bit lines and the one common source line CSL. In this case, a plurality of common source lines CSL may be provided, and the plurality of common source lines CSL may be arranged two-dimensionally. Here, electrically the same voltage may be applied to the plurality of common source lines CSL or each of the common source lines CSL may be also electrically controlled.

Each of the cell strings CSTR may include a ground selection transistor GST connected to the common source line CSL, a string selection transistor SST connected to the bit line BL, and a plurality of memory cell transistors MCT arranged between the ground and string selection transistors GST and SST. Further, the ground selection transistor GST, the string selection transistor SST, and the memory cell transistors MCT may be connected in series.

The common source line CSL may be commonly connected to sources of the ground selection transistors GST. In addition, a ground selection line GSL, a plurality of word lines WL0 to WL3, and a plurality of string selection lines SSL, which are arranged between the common source line CSL and the bit line BL, may be used as electrode layers of the ground selection transistor GST, the memory cell transistors MCT, and the string selection transistors SST. Further, each of the memory cell transistors MCT includes a memory element. Hereinafter, the string selection line SSL may be expressed as an upper selection line USL, and the ground selection line GSL may be expressed as a lower selection line LSL.

Meanwhile, in a three-dimensional flash memory according to the related art, in order to satisfy excellent performance and low price required by consumers, cells are vertically stacked, and thus the degree of integration increases.

For example, referring to FIG. 2 illustrating a structure of the three-dimensional flash memory according to the related art, the three-dimensional flash memory according to the related art is manufactured by arranging an electrode structure 215, in which interlayer insulating layers 211 and horizontal structures 250 are alternately and repeatedly formed, on a substrate 200. The interlayer insulating layers 211 and the horizontal structures 250 may extend in a first direction. The interlayer insulating layers 211 may be, for example, a silicon oxide film, and the lowermost interlayer insulating layer 211a among the interlayer insulating layers 211 may have a thickness lower than those of the other interlayer insulating layers 211. Each of the horizontal structures 250 may include first and second blocking insulating films 242 and 243 and an electrode layer 245. A plurality of the electrode structures 215 are provided, and the plurality of electrode structures 215 may be arranged to face each other in a second direction intersecting the first direction. The first and second directions may correspond to an X axis and a Y axis of FIG. 2, respectively. Trenches 240 spacing the plurality of electrode structures 215 apart from each other may extend between the plurality of electrode structures 215 in the first direction. Highly doped impurity areas may be formed in the substrate 200 exposed by the trenches 240, and thus the common source line CSL may be disposed. Although not illustrated, isolation insulating films filling the trenches 240 may be further arranged.

Vertical structures 230 passing through the electrode structures 215 may be arranged. As an example, in a plan view, the vertical structures 230 may be arranged in a matrix form while being aligned in the first and second directions. As another example, the vertical structures 230 may be aligned in the second direction and may be arranged in a zigzag form in the first direction. Each of the vertical structures 230 may include a protective film 224, a charge storage film 225, a tunnel insulating film 226, and a channel layer 227. As an example, the channel layer 227 may be disposed in a hollow tube shape therein, and in this case, a buried film 228 (formed as an oxide) filling an inside of the channel layer 227 may be further disposed. A drain area D may be disposed on the channel layer 227 and a conductive pattern 229 may be formed on the drain area D and may be connected to the bit line BL. The bit line BL may extend in a direction intersecting the horizontal electrodes 250, for example, in the second direction. As an example, the vertical structures 230 aligned in the second direction may be connected to the one bit line BL.

The first and second blocking insulating films 242 and 243 included in the horizontal structures 250 and the charge storage film 225 and the tunnel insulating film 226 included in the vertical structures 230 may be defined as oxide-nitride-oxide (ONO) layers that are information storage elements of the three-dimensional flash memory. That is, some of the information storage elements may be included in the vertical structures 230, and the other thereof may be included in the horizontal structures 250. As an example, among the information storage elements, the charge storage film 225 and the tunnel insulating film 226 may be included in the vertical structures 230, and the first and second blocking insulating films 242 and 243 may be included in the horizontal structures 250.

Epitaxial patterns 222 may be arranged between the substrate 200 and the vertical structures 230. The epitaxial patterns 222 connect the substrate 200 and the vertical structures 230. The epitaxial patterns 222 may be in contact with at least one layer of the horizontal structures 250. That is, the epitaxial patterns 222 may be arranged in contact with a lowermost horizontal structure 250a. According to another embodiment, the epitaxial patterns 222 may be arranged in contact with a plurality of layers, for example, two layers, of the horizontal structures 250. Meanwhile, when the epitaxial patterns 222 are arranged in contact with the lowermost horizontal structure 250a, the lowermost horizontal structure 250a may be thicker than the other horizontal structures 250. The lowermost horizontal structure 250a in contact with the epitaxial patterns 222 may correspond to the ground selection line GSL of the array of the three-dimensional flash memory described with reference to FIG. 1, and the other horizontal structures 250 in contact with the vertical structures 230 may correspond to the plurality of word lines WL0 to WL3.

Each of the epitaxial patterns 222 has a recessed side wall 222a. Accordingly, the lowermost horizontal structure 250a in contact with the epitaxial patterns 222 is disposed along a profile of the recessed side wall 222a. That is, the lowermost horizontal structure 250a may be disposed in an inwardly convex shape along the recessed side walls 222a of the epitaxial patterns 222.

In relation to the existing three-dimensional flash memory having such a structure, improving leakage current characteristics of the channel layer 227 has recently been spotlighted, and thus a structure in which the channel layer 227 is formed of a material including at least one of In, Zn, or Ga as in an indium gallium zinc oxide (IGZO) or a group 4 semiconductor material has been proposed.

However, the IGZO material has a higher contact resistance than that of polysilicon. Thus, in an existing three-dimensional flash memory 300 including a channel layer 310 formed of the IGZO material illustrated in FIG. 3, an area of a drain junction 311 is small, and thus there is a problem due to a contact resistance with a wiring line 320 such as a drain line positioned at an upper end of at least one string.

Thus, a technology for solving the contact resistance problem of the IGZO channel layer 310 of the existing three-dimensional flash memory 300 needs to be proposed.

### DETAILED DESCRIPTION OF THE INVENTION

### Technical Problem

Embodiments propose a three-dimensional flash memory having a structure in which an area of a drain junction is maximally increased to improve a contact resistance of a channel layer formed of a material having excellent leakage current characteristics but having a higher contact resistance than that of polysilicon, and a method of manufacturing the same.

### Technical Solution

According to an embodiment, a three-dimensional flash memory includes a plurality of word lines extending on a substrate in a horizontal direction and sequentially stacked, and at least one string passing through the plurality of word lines and extending on the substrate in a vertical direction, the at least one string including a channel layer extending in the vertical direction and a charge storage layer formed to surround the channel layer, wherein the at least one string includes a drain junction having a double structure including a first area N+ doped in the channel layer and a second area N+ doped with a material having a smaller contact resistance than that of the channel layer.

According to an aspect, the second area may be formed in an internal space of the first area as the material having the smaller contact resistance than that of the channel layer is filled in an internal space of the channel layer formed in a macaroni shape having an empty inside.

According to another aspect, the material having the smaller contact resistance than that of the channel layer may be filled only in an upper end portion of the internal space of the channel layer.

According to still another aspect, the at least one string may have a structure in which an area of the drain junction is maximally increased as the drain junction is formed in the double structure.

According to yet another aspect, the at least one string may have a structure in which a contact area of the channel layer is maximally increased as the drain junction is formed in the double structure.

According to yet another aspect, the channel layer may be formed of a material including at least one of In, Zn, or Ga or a group 4 semiconductor material to suppress or block a leakage current, and the material having the smaller contact resistance than that of the channel layer may be polysilicon.

According to an embodiment, a method of manufacturing a three-dimensional flash memory includes preparing a semiconductor structure including a plurality of word lines extending on a substrate in a horizontal direction and sequentially stacked, and at least one string passing through the plurality of word lines and extending on the substrate in a vertical direction, the at least one string including a channel layer extending in the vertical direction and a charge storage layer formed to surround the channel layer, forming a first area included in a drain junction having a double structure by N+ doping an upper end portion of the channel layer, etching an upper end portion of an internal area of the channel layer, and forming a second area included in the drain junction having the double structure in the etched space, the second area being N+ doped with a material having a smaller contact resistance than that of the channel layer.

According to an embodiment, a three-dimensional flash memory includes a plurality of word lines extending on a substrate in a horizontal direction and sequentially stacked, and at least one string passing through the plurality of word lines and extending on the substrate in a vertical direction, the at least one string including a channel layer extending in the vertical direction and a charge storage layer formed to surround the channel layer, wherein the at least one string includes a drain junction having a double structure including a first area N+ doped in the channel layer and a second area formed of the same material as a material constituting a wiring line disposed above the at least one string.

According to an aspect, the second area may be formed in an internal space of the first area as the same material as the material constituting the wiring line is filled in an internal space of the channel layer formed in a macaroni shape having an empty inside.

According to another aspect, the same material as the material constituting the wiring line may be filled only in an upper end portion of the internal space of the channel layer.

According to still another aspect, the at least one string may have a structure in which an area of the drain junction is maximally increased as the drain junction is formed in the double structure.

According to yet another aspect, the at least one string may have a structure in which a contact area of the channel layer is maximally increased as the drain junction is formed in the double structure.

According to yet another aspect, the channel layer may be formed of a material including at least one of In, Zn, or Ga or a group 4 semiconductor material to suppress or block a leakage current.

According to an embodiment, a method of manufacturing a three-dimensional flash memory includes preparing a semiconductor structure including a plurality of word lines extending on a substrate in a horizontal direction and sequentially stacked, and at least one string passing through the plurality of word lines and extending on the substrate in a vertical direction, the at least one string including a channel layer extending in the vertical direction and a charge storage layer formed to surround the channel layer, forming a first area included in a drain junction having a double structure by N+ doping an upper end portion of the channel layer, etching an upper end portion of an internal area of the channel layer, and forming a second area included in the drain junction having the double structure in the etched space, the second area being formed of the same material as a material constituting a wiring line disposed above the at least one string.

### Advantageous Effects of the Invention

Embodiments propose a three-dimensional flash memory having a structure in which an area of a drain junction is maximally increased in relation to a channel layer formed of a material having excellent leakage current characteristics but having a higher contact resistance than that of polysilicon, and a method of manufacturing the same. Thus, the contact resistance of the channel layer may be improved.

### DESCRIPTION OF THE DRAWINGS

FIG. 1 is a schematic circuit diagram illustrating an array of a three-dimensional flash memory according to the related art.

FIG. 2 is a perspective view illustrating a structure of the three-dimensional flash memory according to the related art.

FIG. 3 is a side cross-sectional view illustrating the three-dimensional flash memory according to the related art.

FIG. 4 is a side cross-sectional view illustrating a three-dimensional flash memory according to an embodiment.

FIG. 5 is a flowchart illustrating a method of manufacturing the three-dimensional flash memory according to the embodiment.

FIGS. 6A to 6D are side cross-sectional views illustrating the three-dimensional flash memory to describe the manufacturing method illustrated in FIG. 5.

FIG. 7 is a side cross-sectional view illustrating a three-dimensional flash memory according to another embodiment.

FIG. 8 is a flowchart illustrating a method of manufacturing the three-dimensional flash memory according to another embodiment.

FIGS. 9A to 9D are side cross-sectional views illustrating the three-dimensional flash memory to describe the manufacturing method illustrated in FIG. 8.

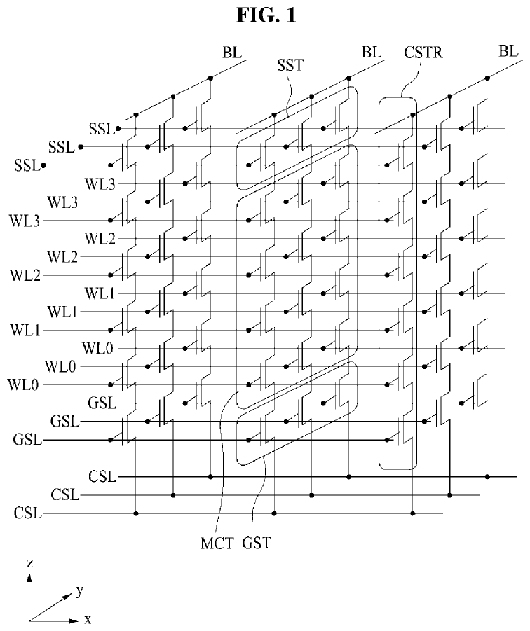

### BEST MODE

Hereinafter, embodiments will be described in detail with reference to the accompanying drawings. However, the present disclosure is not restricted or limited by the embodiments. Further, the same reference numerals in each drawing indicate the same components.

Further, terms used in the present specification are used to properly express the embodiments of the present disclosure, and the terms may change depending on the intention of a user or an operator or customs in the field to which the present disclosure belongs. Therefore, definitions of the present terms should be made based on the contents throughout the present specification.

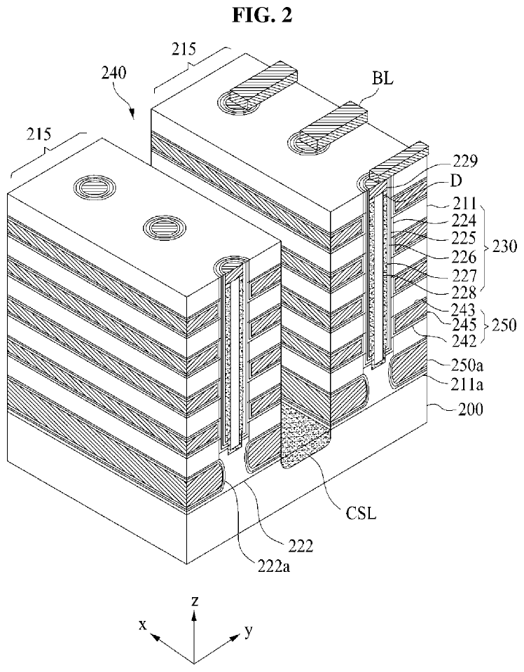

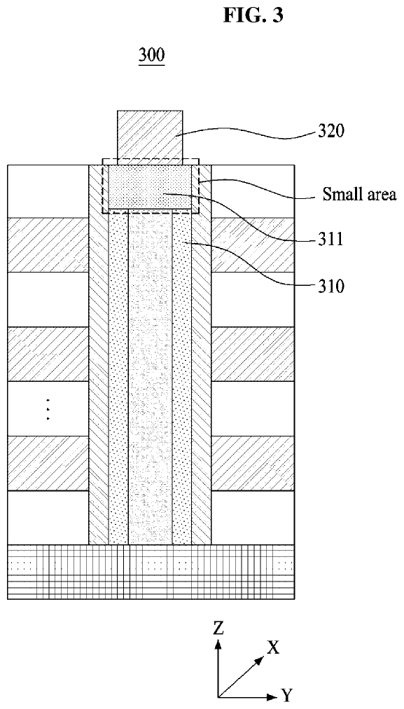

Hereinafter, in a side cross-sectional view illustrating a three-dimensional flash memory, for convenience of description, a three-dimensional flash memory will be illustrated and described while components such as a source line positioned below a plurality of strings are omitted. However, the three-dimensional flash memory, which will be described below, is not restricted and limited thereto, and may further include an additional component on the basis of a structure of the three-dimensional flash memory illustrated with reference to FIG. 2.

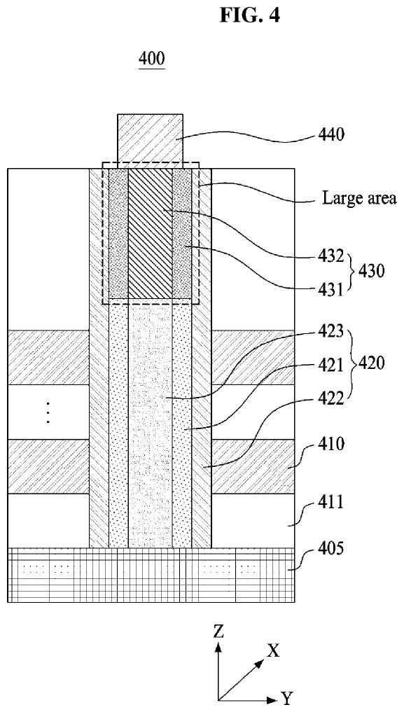

FIG. 4 is a side cross-sectional view illustrating a three-dimensional flash memory according to an embodiment.

Referring to FIG. 4, a three-dimensional flash memory 400 according to the embodiment includes a plurality of word lines 410 and at least one string 420.

The plurality of word lines 410 are sequentially stacked while extending on a substrate 405 in a horizontal direction, are made of a conductive material such as W (tungsten), Ti (titanium), Ta (tantalum), Cu (copper), Mo (molybdenum), Ru (ruthenium), or Au (gold) (including all metallic materials capable of forming ALD in addition to the above-described metallic materials), apply a voltage to memory cells corresponding thereto, and perform a memory operation (a reading operation, a program operation, an erasure operation, or the like). A plurality of insulating layers 411 made of an insulating material may be interposed between the plurality of word lines 410.

A string selection line (SSL) may be disposed at a top of the plurality of word lines 410, and a ground selection line (GSL) may be disposed at a bottom thereof.

The at least one string 420 passes through the plurality of word lines 410, extends on the substrate 405 in a vertical direction, includes a channel layer 421 and a charge storage layer 422, and thus may constitute a plurality of memory cells corresponding to the plurality of word lines 410.

The charge storage layer 422 is a component that traps charges or holes by a voltage applied through the plurality of word lines 410 or maintains states of charges (e.g., polarization states of charges) while extending to surround the channel layer 421 and may serve as a data storage in the three-dimensional flash memory 400. As an example, an oxide-nitride-oxide (ONO) layer or a ferroelectric layer may be used as the charge storage layer 422. The charge storage layer 422 is not restricted or limited to the extending to surround the channel layer 421 and may also have a structure separated for each memory cell while surrounding the channel layer 421.

The channel layer 421 is a component that performs a memory operation by a voltage applied through the plurality of word lines 410, the SSL, the GSL, and the bit line and may be formed of a material having excellent leakage current characteristics but having a higher contact resistance than that of polysilicon, such as a material including at least one of In, Zn, or Ga or a group 4 semiconductor material.

A buried film 423 may be formed inside the channel layer 421. As an example, as the channel layer 421 has a macaroni shape having an empty inside, the oxide buried film 423 may be formed in an internal space of the channel layer 421.

In particular, the at least one string 420 may include a drain junction 430 formed in a double structure and thus may have a structure in which an area of the drain junction 430 is maximally increased.

In more detail, the drain junction 430 may have the double structure including a first area 431 N+ doped in the channel layer 421 and a second area 432 N+ doped with a material (e.g., polysilicon) having a lower contact resistance than that of the channel layer 421. Thus, the drain junction 430 may have the double structure and thus have a structure in which the area is maximally increased. Therefore, the drain junction 430 has a structure in which a contact area of the channel layer 421 is maximally increased, and thus a large contact resistance of the channel layer 421 may be improved (decreased). Hereinafter, the fact that the drain junction 430 has a structure of which an area is maximally increased refers to a state in which the drain junction 430 has a structure of which an area is maximally increased on a remaining area of the at least one string 420 except for an area in which the plurality of memory cells are implemented on the premise that the number of the plurality of memory cells included in the at least one string 420 is implemented as a planned number. Likewise, the fact that the channel layer 421 has a structure of which a contact area is maximally increased refers to a state in which the channel layer 421 has a structure of which a contact area is maximally increased on a remaining area of the at least one string 420 except for an area in which the plurality of memory cells are implemented on the premise that the number of memory cells included in the at least one string 420 is implemented as a planned number.

With regard to the double structure of the drain junction 430, as illustrated in the drawing, the second area 432 may be formed in an internal space of the first area 431 as a material having a smaller contact resistance than that of the channel layer 421 is filled in an internal space of the channel layer 421 formed in a macaroni shape having an empty inside. As an example, the material having a smaller contact resistance than that of the channel layer 421 is filled only at an upper end portion of the internal space of the channel layer 421, and thus the second area 432 may be formed at an upper end portion of the at least one string 420. Likewise, the first area 431 may also be formed at the upper end portion of the at least one string 420.

A wiring line 440 such as a drain line may be disposed above the at least one string 420 (more accurately, above the drain junction 430).

In this way, the drain junction 430 may have a structure of which an area is maximally increased through the double structure including the first area 431 N+ doped in the channel layer 421 and the second area 432 N+ doped with the material having a smaller contact resistance than that of the channel layer 421, and based on this, a contact resistance of the channel layer 421 for the wiring line 440 may be improved.

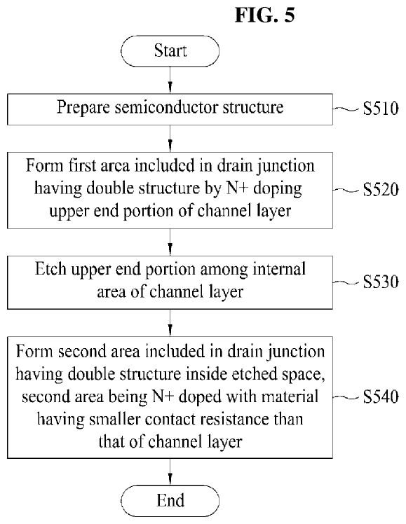

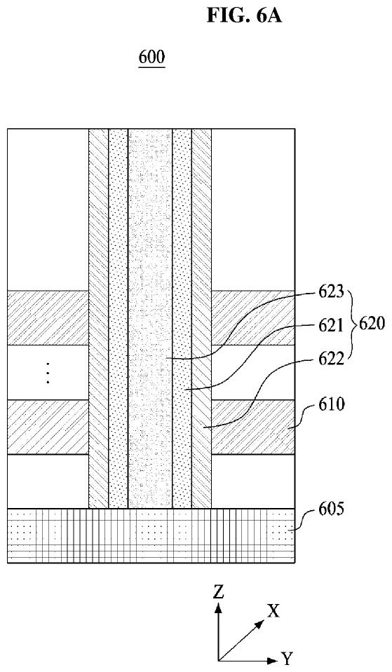

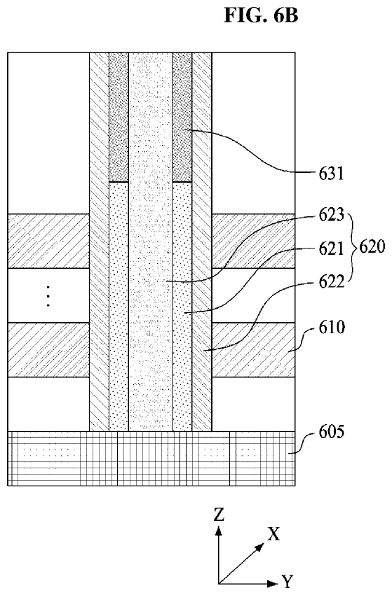

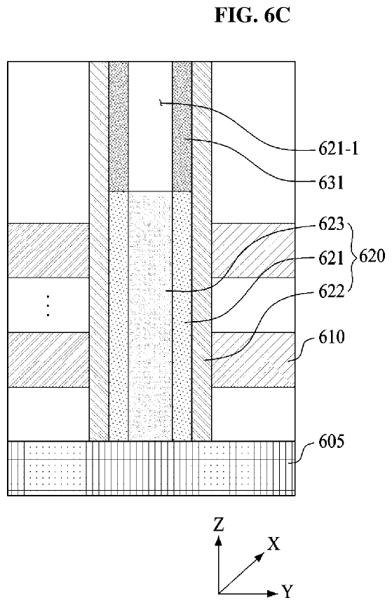

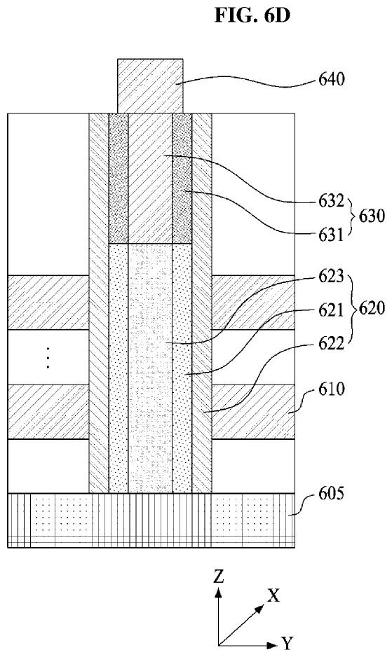

FIG. 5 is a flowchart illustrating a method of manufacturing the three-dimensional flash memory according to the embodiment, and FIGS. 6A to 6D are side cross-sectional views illustrating the three-dimensional flash memory to describe the manufacturing method illustrated in FIG. 5.

Hereinafter, the manufacturing method, which will be described below, is based on the premise that the manufacturing method is performed by an automated and mechanized manufacturing system, and the three-dimensional flash memory completely manufactured through the manufacturing method may have the structure described with reference to FIG. 4.

Referring to FIG. 5, in operation S510, a manufacturing system according to the embodiment may prepare a semiconductor structure 600 as in FIG. 6A.

Here, the semiconductor structure 600 may include a plurality of word lines 610 extending on a substrate 605 in a horizontal direction and sequentially stacked and at least one string 620 passing through the plurality of word lines 610 and extending on the substrate 605 in a vertical direction. The at least one string 620 may include a channel layer 621 extending in a vertical direction and a charge storage layer 622 extending in a vertical direction to surround the channel layer 621.

In this case, the channel layer 621 may be formed of a material having excellent leakage current characteristics but having a higher contact resistance than that of polysilicon, such as a material including at least one of In, Zn or Ga or a group 4 semiconductor material. The channel layer 621 may be formed in a macaroni shape having an empty inside and may include a buried film 623 therein.

Next, in operation S520, the manufacturing system may form a first area 631 included in a drain junction 630 having a double structure by N+ doping an upper end portion of the channel layer 621 as in FIG. 6B.

Next, in operation S530, the manufacturing system may etch the upper end portion among an internal area of the channel layer 621 as in FIG. 6C. As an example, the manufacturing system may secure a space 621-1 by etching an upper end portion of the buried film 623 included in the channel layer 621.

Thereafter, in operation S540, the manufacturing system may form a second area 632 included in the drain junction 630 having the double structure inside an etched space 621-1 as in FIG. 6D. Here, the second area 632 may be an area N+ doped with a material (e.g., polysilicon) having a smaller contact resistance than that of the channel layer 621. For example, the manufacturing system may form the second area 632 by filling the etched space 621-1 with the material (e.g., polysilicon) having a smaller contact resistance than that of the channel layer 621 and then N+ doping the etched space 621-2.

Although not illustrated in FIG. 5 as a separate operation, after operations S510 to S540 are performed in this way, the manufacturing system may place a wiring line 640 on the at least one string 620 as in FIG. 6D.

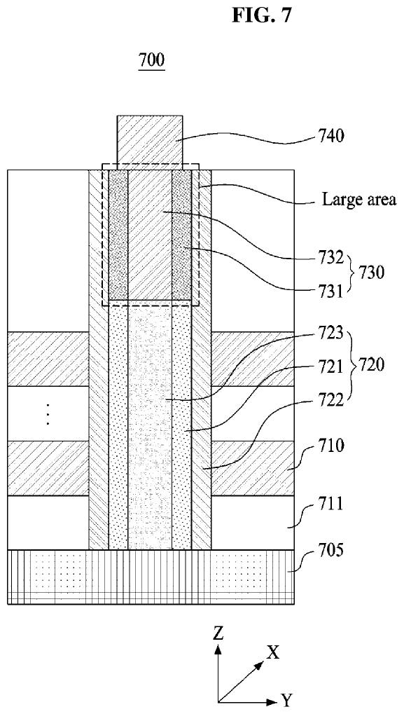

FIG. 7 is a side cross-sectional view illustrating a three-dimensional flash memory according to another embodiment.

Referring to FIG. 7, a three-dimensional flash memory 700 according to another embodiment has the same structure (the drain junction having the double structure) as that of the three-dimensional flash memory 400 described with reference to FIG. 4 but is different from the three-dimensional flash memory 400 in that the material constituting the second area included in the drain junction having the double structure is different from that of the three-dimensional flash memory 400. A detailed description thereof will be made below.

The three-dimensional flash memory 700 includes a plurality of word lines 710 and at least one string 720.

The plurality of word lines 710 are sequentially stacked while extending on a substrate 705 in a horizontal direction, are made of a conductive material such as W (tungsten), Ti (titanium), Ta (tantalum), Cu (copper), Mo (molybdenum), Ru (ruthenium), or Au (gold) (including all metallic materials capable of forming ALD in addition to the above-described metallic materials), apply a voltage to memory cells corresponding thereto, and perform a memory operation (a reading operation, a program operation, an erasure operation, or the like). A plurality of insulating layers 711 made of an insulating material may be interposed between the plurality of word lines 710.

An SSL may be disposed at a top of the plurality of word lines 710, and a GSL may be disposed at a bottom thereof.

The at least one string 720 passes through the plurality of word lines 710, extends on the substrate 705 in a vertical direction, includes a channel layer 721 and a charge storage layer 722, and thus may constitute a plurality of memory cells corresponding to the plurality of word lines 710.

The charge storage layer 722 is a component that traps charges or holes by a voltage applied through the plurality of word lines 710 or maintains states of charges (e.g., polarization states of charges) while extending to surround the channel layer 721 and may serve as a data storage in the three-dimensional flash memory 700. As an example, an ONO layer or a ferroelectric layer may be used as the charge storage layer 722.

The channel layer 721 is a component that performs a memory operation by a voltage applied through the plurality of word lines 710, the SSL, the GSL, and the bit line and may be formed of a material having excellent leakage current characteristics but having a higher contact resistance than that of polysilicon, such as a material including at least one of In, Zn, or Ga or a group 4 semiconductor material.

A buried film 723 may be formed inside the channel layer 721. As an example, as the channel layer 721 has a macaroni shape having an empty inside, the oxide buried film 723 may be formed in an internal space of the channel layer 721.

In particular, the at least one string 720 may include a drain junction 730 formed in a double structure and thus may have a structure in which an area of the drain junction 730 is maximally increased.

In more detail, the drain junction 730 may have the double structure including a first area 731 N+ doped in the channel layer 721 and a second area 732 formed of the same material as a material (e.g., a conductive material such as W (tungsten), Ti (titanium), Ta (tantalum), Cu (copper), Mo (molybdenum), Ru (ruthenium), or Au (gold)) constituting a wiring line 740 disposed above the at least one string 720. Thus, the drain junction 730 may have the double structure and thus have a structure in which the area is maximally increased. Therefore, the drain junction 430 has a structure in which a contact area of the channel layer 721 is maximally increased, and thus a large contact resistance of the channel layer 721 may be improved (decreased). Hereinafter, the fact that the drain junction 730 has a structure of which an area is maximally increased refers to a state in which the drain junction 730 has a structure of which an area is maximally increased on a remaining area of the at least one string 720 except for an area in which the plurality of memory cells are implemented on the premise that the number of memory cells included in the at least one string 720 is implemented as a planned number. Likewise, the fact that the channel layer 721 has a structure of which a contact area is maximally increased refers to a state in which the channel layer 721 has a structure of which a contact area is maximally increased on a remaining area of the at least one string 720 except for an area in which the plurality of memory cells are implemented on the premise that the number of the plurality of memory cells included in the at least one string 720 is implemented as a planned number.

With regard to the double structure of the drain junction 730, as illustrated in the drawing, the second area 732 may be formed in an internal space of the first area 731 as the same material as a material constituting the wiring line 740 is filled in the internal space of the channel layer 721 formed in a macaroni shape having an empty inside. As an example, the same material as the material constituting the wiring line 740 is filled only at an upper end portion of the internal space of the channel layer 721, and thus the second area 732 may be formed at an upper end portion of the at least one string 720. Likewise, the first area 731 may also be formed at the upper end portion of the at least one string 720.

The wiring line 740 such as a drain line may be disposed above the at least one string 720 (more accurately, above the drain junction 730).

In this way, the drain junction 730 may have a structure of which an area is maximally increased through the double structure including the first area 731 N+ doped in the channel layer 721 and the second area 732 formed of the same material as the material constituting the wiring line 740, and based on this, a contact resistance of the channel layer 421 for the wiring line 740 may be improved.

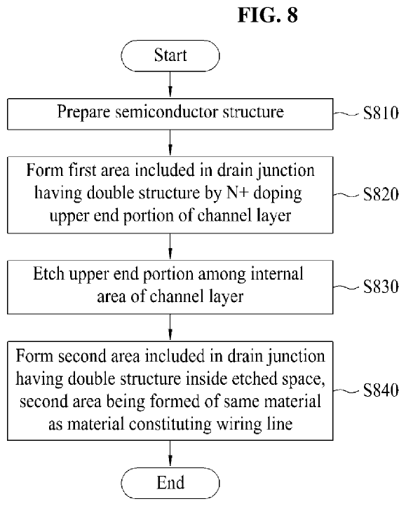

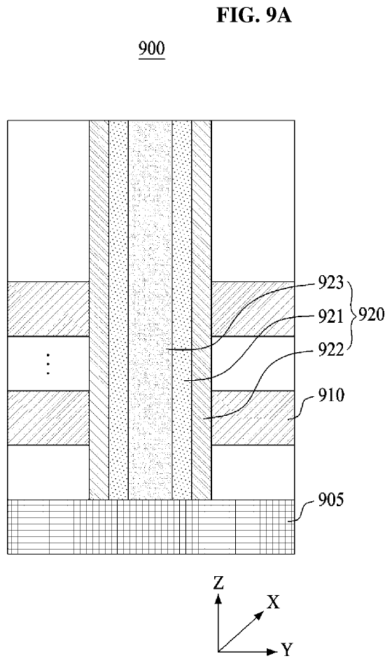

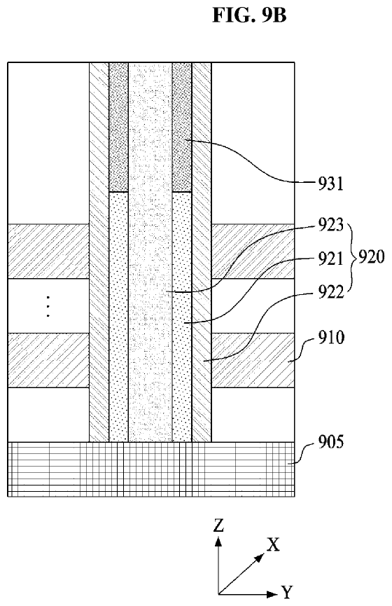

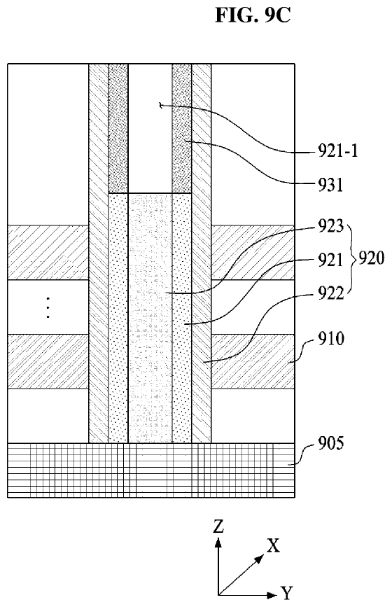

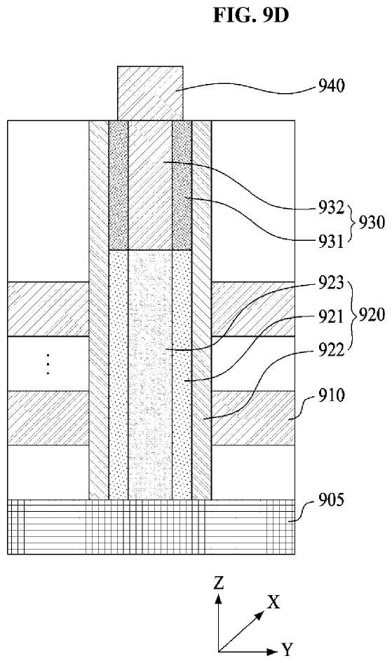

FIG. 8 is a flowchart illustrating a method of manufacturing the three-dimensional flash memory according to another embodiment, and FIGS. 9A to 9D are side cross-sectional views illustrating the three-dimensional flash memory to describe the manufacturing method illustrated in FIG. 8.

Hereinafter, the manufacturing method, which will be described below, is based on the premise that the manufacturing method is performed by an automated and mechanized manufacturing system, and the three-dimensional flash memory completely manufactured through the manufacturing method may have the structure described with reference to FIG. 7.

Referring to FIG. 8, in operation S810, a manufacturing system according to the embodiment may prepare a semiconductor structure 900 as in FIG. 9A.

Here, the semiconductor structure 900 may include a plurality of word lines 910 extending on a substrate 905 in a horizontal direction and sequentially stacked and at least one string 920 passing through the plurality of word lines 910 and extending on the substrate 905 in a vertical direction. The at least one string 920 may include a channel layer 921 extending in a vertical direction and a charge storage layer 922 extending in a vertical direction to surround the channel layer 921.

In this case, the channel layer 921 may be formed of a material having excellent leakage current characteristics but having a higher contact resistance than that of polysilicon, such as a material including at least one of In, Zn or Ga or a group 4 semiconductor material. The channel layer 921 may be formed in a macaroni shape having an empty inside and may include a buried film 923 therein.

Next, in operation S820, the manufacturing system may form a first area 931 included in a drain junction 930 having a double structure by N+ doping an upper end portion of the channel layer 921 as in FIG. 9B.

Next, in operation S830, the manufacturing system may etch the upper end portion among an internal area of the channel layer 921 as in FIG. 9C. As an example, the manufacturing system may secure a space 921-1 by etching an upper end portion of the buried film 923 included in the channel layer 921.

Thereafter, in operation S840, the manufacturing system may form a second area 932 included in the drain junction 930 having the double structure inside an etched space 921-1 as in FIG. 9D. Here, the second area 932 may be formed of the same material as a material constituting the wiring line 940 disposed above the at least one string 920. For example, the manufacturing system may form the second area 932 by filling the etched space 921-1 with the same material as the material (e.g., a conductive material such as W (tungsten), Ti (titanium), Ta (tantalum), Cu (copper), Mo (molybdenum), Ru (ruthenium), or Au (gold)) constituting the wiring line 940.

Although not illustrated as a separate operation in FIG. 8, after operations S810 to S840 are performed, the manufacturing system may dispose the wiring line 940 formed of a conductive material such as a conductive material such as W (tungsten), Ti (titanium), Ta (tantalum), Cu (copper), Mo (molybdenum), Ru (ruthenium), or Au (gold) above the at least one string 920 as in FIG. 9D.

As described above, although the embodiments have been described with reference to the limited embodiments and the limited drawings, various modifications and changes may be made based on the above description by those skilled in the art. For example, even though the described technologies are performed in an order different from the described method, and/or the described components such as a system, a structure, a device, and a circuit are coupled or combined in a form different from the described method or are replaced or substituted by other components or equivalents, appropriate results may be achieved.

Therefore, other implementations, other embodiments, and those equivalent to the appended claims also belong to the scope of the appended claims.

1. A three-dimensional flash memory comprising:
a plurality of word lines extending on a substrate in a horizontal direction and sequentially stacked; and
at least one string passing through the plurality of word lines and extending on the substrate in a vertical direction, the at least one string including a channel layer extending in the vertical direction and a charge storage layer formed to surround the channel layer,
wherein the at least one string includes a drain junction having a double structure including a first area N+ doped in the channel layer and a second area N+ doped with a material having a smaller contact resistance than that of the channel layer.

2. The three-dimensional flash memory of claim 1, wherein the second area is formed in an internal space of the first area as the material having the smaller contact resistance than that of the channel layer is filled in an internal space of the channel layer formed in a macaroni shape having an empty inside.

3. The three-dimensional flash memory of claim 2, wherein the material having the smaller contact resistance than that of the channel layer is filled only in an upper end portion of the internal space of the channel layer.

4. The three-dimensional flash memory of claim 1, wherein the at least one string has a structure in which an area of the drain junction is maximally increased as the drain junction is formed in the double structure.

5. The three-dimensional flash memory of claim 4, wherein the at least one string has a structure in which a contact area of the channel layer is maximally increased as the drain junction is formed in the double structure.

6. The three-dimensional flash memory of claim 1, wherein the channel layer is formed of a material including at least one of In, Zn, or Ga or a group 4 semiconductor material to suppress or block a leakage current, and
the material having the smaller contact resistance than that of the channel layer is polysilicon.

7. A method of manufacturing a three-dimensional flash memory, the method comprising:
preparing a semiconductor structure including a plurality of word lines extending on a substrate in a horizontal direction and sequentially stacked, and at least one string passing through the plurality of word lines and extending on the substrate in a vertical direction, the at least one string including a channel layer extending in the vertical direction and a charge storage layer formed to surround the channel layer;
forming a first area included in a drain junction having a double structure by N+ doping an upper end portion of the channel layer;
etching an upper end portion of an internal area of the channel layer; and
forming a second area included in the drain junction having the double structure in the etched space, the second area being N+ doped with a material having a smaller contact resistance than that of the channel layer.

8. A three-dimensional flash memory comprising:
a plurality of word lines extending on a substrate in a horizontal direction and sequentially stacked; and
at least one string passing through the plurality of word lines and extending on the substrate in a vertical direction, the at least one string including a channel layer extending in the vertical direction and a charge storage layer formed to surround the channel layer,
wherein the at least one string includes a drain junction having a double structure including a first area N+ doped in the channel layer and a second area formed of the same material as a material constituting a wiring line disposed above the at least one string.

9. The three-dimensional flash memory of claim 8, wherein the second area is formed in an internal space of the first area as the same material as the material constituting the wiring line is filled in an internal space of the channel layer formed in a macaroni shape having an empty inside.

10. The three-dimensional flash memory of claim 9, wherein the same material as the material constituting the wiring line is filled only in an upper end portion of the internal space of the channel layer.

11. The three-dimensional flash memory of claim 8, wherein the at least one string has a structure in which an area of the drain junction is maximally increased as the drain junction is formed in the double structure.

12. The three-dimensional flash memory of claim 11, wherein the at least one string has a structure in which a contact area of the channel layer is maximally increased as the drain junction is formed in the double structure.

13. The three-dimensional flash memory of claim 11, wherein the channel layer is formed of a material including at least one of In, Zn, or Ga or a group 4 semiconductor material to suppress or block a leakage current.

14. A method of manufacturing a three-dimensional flash memory, the method comprising:
preparing a semiconductor structure including a plurality of word lines extending on a substrate in a horizontal direction and sequentially stacked, and at least one string passing through the plurality of word lines and extending on the substrate in a vertical direction, the at least one string including a channel layer extending in the vertical direction and a charge storage layer formed to surround the channel layer;
forming a first area included in a drain junction having a double structure by N+ doping an upper end portion of the channel layer;
etching an upper end portion of an internal area of the channel layer; and
forming a second area included in the drain junction having the double structure in the etched space, the second area being formed of the same material as a material constituting a wiring line disposed above the at least one string.
